(19) United States
(12) Patent Application Publication
(10) Pub. No.: US 2006/0081881 A1
(43) Pub. Date: Apr. 20, 2006

(54) Circuit wiring laying-out apparatus, method of laying-out a circuit, signal-bearing medium embodying a program of laying-out wiring, wiring layout, and method of using a wiring layout

(75) Inventor: Takashi Gotou, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Corporation, Tokyo (JP)

(21) Appl. No.: 11/250,581

(22) Filed: Oct. 17, 2005

(30) Foreign Application Priority Data
Oct. 18, 2004 (JP) 2004-302723

(51) Int. Cl. H01L 27/10

(52) U.S. Cl. 257/202

(57) ABSTRACT

A circuit wiring laying-out apparatus includes a wiring device that moves automatically a wiring in a first region to a second region, to make uniform a number of wirings in the circuit.

### BACKGROUND OF THE INVENTION

The present invention relates to circuit wiring laying-out apparatus, method of laying-out a circuit, signal-bearing medium embodying a program of laying-out wiring, wiring layout, and method of using a wiring layout.

In a circuit (e.g., LSI (Large Scale Logical Integrated Circuit)) manufacturing, CMP (Chemical Mechanical Polish) method is adopted.

### SUMMARY OF THE INVENTION

In the design of a circuit, for example, an LSI wiring density must be uniform in each wiring layer of the LSI. However, the wiring processes have been implemented from the viewpoint of minimization of the total length of wirings within the LSI, and realization of the necessary performance of LSI (operation frequency). Therefore, wiring density in the LSI has fluctuated.

As disclosed in patent documents 1 (JP-A No. 2001-274255) and 2 (JP-A No. 1998-335333), dummy wiring patterns have been inserted into an idle region of wiring in the LSI, and the wiring density has been flattened after completion of all wiring processes for ordinary signals power sources and clocks. However, for the regions where the wirings are complex and local wiring density is high, backward processes such as manual correction of signal wirings for equalization of wiring density have been performed.

Moreover, dummy wirings have been inserted until all wiring regions of LSI can satisfy the constant wiring density, or until the-maximum wiring density to be accommodated I within the relevant wiring layer can be satisfied. However, if fluctuation in wiring density is large, then the amount of data and processing time required for dummy wirings increase.

As explained above, when equalization in the wiring density progresses, the number of processing steps increases correspondingly in the LSI design in the conventional methods. For example, extra processes for manual correction and dummy wirings are closely linked to equalization in the wiring density.

In view of the foregoing and other exemplary problems, drawbacks, and disadvantages of the conventional techniques, it is an exemplary feature of the present invention to provide an LSI layout apparatus reducing the extra processes for design of an LSI by automatic wiring process to attain uniform wiring density of the LSI.

For example, the present invention provides an LSI layout apparatus that reduces (if not eliminates) manual correction of signal wirings and the amount of data and processing time for embedding dummy wirings to the region where the wiring density is small for equalizing wiring density in each wiring layer of an LSI.

The present invention provides a circuit wiring laying-out apparatus which includes a wiring device that moves automatically a wiring in a first region to a second region, to make uniform a number of wirings in the circuit.

The circuit may include an LSI (Large Scale Integrated Circuit).

When a number of the wirings in said first region exceeds a number of allowable wirings, the wiring device may move the wiring to the second region.

The circuit may have a single wiring layer.

The circuit may include a plurality of wiring layers and the second region is on a second wiring layer.

The wiring device may be devoid of a dummy wiring.

The circuit wiring laying-out apparatus may further include a global wiring capacity computing device that computes the number of allowable wirings passing the first region.

The circuit wiring device may include a global wiring device that executes the wiring so that the number of wirings passing the first region becomes substantially equal to or less than the allowable number of wirings, when the number of the wirings in the first region exceeds the number of allowable wirings.

When the number of the wirings in the first region exceeds the number of allowable wirings, the global wiring device may move the wiring to the second region so that a length of wiring becomes shorter and the wiring passes the second region in which a less number of wirings are laid.

The circuit wiring laying-out apparatus may include a various libraries/layout information inputting device that inputs an information required for laying-out of the circuit, a design rule inputting device that inputs a design rule to be satisfied for processing an insulating film on the circuit, the global wiring capacity computing device that computes the number of allowable wirings passing each partial region to accommodate a global wiring passing coefficient of a unit region within a constant range by referring to the design rule inputted with the design rule inputting device, the global wiring device that implements a global wiring and updates a laying-out wiring information to maintain the number of global wirings in the partial region less than or equal to the allowable number of wirings by referring to the layout information of actual terminal, the global wiring device connecting relationship among the actual terminals, and the allowable number of passing global wirings from the laying-out wiring information inputted with the various libraries/layout information inputting device, a detail wiring device that executes detail wiring in each the partial region and updates the layout wiring information, for the global wiring determined by the global wiring device, and a laying-out wiring information outputting device that outputs the wiring information of circuit altered by the detail wiring device.

The present invention also provides a circuit wiring laying-out apparatus which includes means for moving automatically a wiring in a first region to a second region to make uniform a number of wirings in the circuit, and means for computing an allowable number of wirings passing the first region, wherein, when a number of the wirings in the first region exceeds a number of allowable wirings, the wiring device moves the wiring to the second region.

The present invention also provides a method of laying-out a circuit wiring which includes moving automatically a wiring in a first region to a second region to make uniform a number of wirings in the circuit.

The method of laying-out the circuit wiring may further include providing the circuit to have an LSI (Large Scale Integrated Circuit).

The method of laying-out the circuit wiring may further include when a number of the wirings in the first region exceeds a number of allowable wirings, moving the wiring to the second region.

The method of laying-out the circuit may further include providing the circuit to have a single layer.

The method of laying-out the circuit wiring may further include providing the circuit to include a plurality of wiring layers and the second region is on a second wiring layer.

The method of laying-out the circuit wiring may include providing the circuit wiring devoid of a dummy wiring.

The method of laying-out the circuit wiring may further include computing the number of allowable wirings passing the first region.

The method of laying-out the circuit wiring may further include when the number of the wirings in the first region exceeds the number of allowable wirings, executing the wiring so that the number of wirings passing the first region becomes substantially equal to or less than the allowable number of wirings.

The method of laying-out the circuit wiring may further include when a number of the wirings in the first region exceeds a number of allowable wirings, moving the wiring to the second region so that a length of wiring becomes shorter and the wiring passes the second region in which a less number of wirings may be laid.

The method of laying-out the circuit wiring may include inputting an information required for laying-out of the circuit, inputting a design rule to be satisfied for processing an insulating film on the circuit, computing the number of allowable wirings passing each partial region to accommodate a global wiring passing coefficient of a unit region within a constant range by referring to the design rule, implementing global wiring and updating a laying-out wiring information to maintain the number of global wirings in the partial region less than or equal to the allowable number of wirings by referring to the layout information of actual terminal, the global wiring device connecting relationship among the actual terminals, and the allowable number of passing global wirings from the laying-out wiring information inputted with the various libraries/layout information inputting device, executing detail wiring in each the partial region and updating the layout wiring information, for the global wiring, and outputting the wiring information of the circuit.

The present invention also provides a signal-bearing medium embodying a program of machine-readable instructions executable by a digital processing apparatus, the program causing a wiring laying-out apparatus to perform a method described above.

The present invention also provides a wiring layout which includes a substantially uniform number of wirings devoid of a dummy wiring.

The present invention also provides a method of using a wiring layout which includes processing a circuit including a substantially uniform number of wirings and devoid of a dummy wiring based on the wiring layout.

According to the present invention, manual correction of signal wirings for equalizing wiring density can be reduced by moving a wiring to another region automatically, to make uniform a number of wirings in the LSI. For example, equalizing wiring density can be reduced with automatic wirings to equalize the wiring density in each wiring layer(s) of an LSI by considering manufacturing restrictions and constraints.

Moreover, for example, the amount of data and processing tine required for embedding the dummy wirings in the region where the wiring density is small, can also be reduced, if not eliminated.

### BRIEF DESCRIPTION OF THE DRAWINGS

The novel and exemplary features believed characteristic of the invention are set forth in the appended claims. The invention itself, however, as well as other exemplary features and advantages thereof, will be best understood by reference to the detailed description which follows, read in conjunction with the accompanying drawings, wherein:

FIG. 1 shows an exemplary diagram illustrating an exemplary embodiment of the present invention;

FIG. 2 shows an exemplary flowchart showing operations of the exemplary embodiment;

FIG. 3 shows an exemplary diagram illustrating actual terminals 501 before the global wirings and the connecting relationship among the actual terminals 501;

FIGS. 4A-4C show an exemplary diagram illustrating counting of the global wirings 504;

FIG. 5 shows an exemplary diagram illustrating an example of global wirings 504 started from that of the short wiring distance;

FIG. 6 shows an exemplary diagram illustrating an example where all global wirings 504 have been conducted (e.g., executed);

FIG. 7 shows an exemplary diagram of a two-layer structure illustrating a condition where detail wirings 511 have been completed; and

FIG. 8 shows an exemplary diagram of a single layer structure illustrating the condition where the detail wirings 511 have been completed.

### DETAILED DESCRIPTION OF THE EXEMPLARY EMBODIMENTS

In this exemplary embodiment, the exemplary automatic wiring for equalizing the wiring density has been realized as will be explained below.

Technical terms used in this exemplary embodiment will be explained below as an example. In this exemplary embodiment, a wiring layer of a circuit (e.g., an LSI) is formed of two layers called a “first metal layer” and a “second metal layer”.

“Contact 513” may be used for connecting the wiring of the first metal layer and the wiring of the second metal layer.

“Global wiring 504” may be the wiring which has been decided in the region to pass among the unit regions segmented by the boundary lines. The global wiring is formed of an element connecting an actual terminal 501 and a virtual terminal 502 (terminal on the boundary line).

“Conduct of detail wiring 511” may represent assignment of the wiring layer for each unit region and decision of location of the contact.

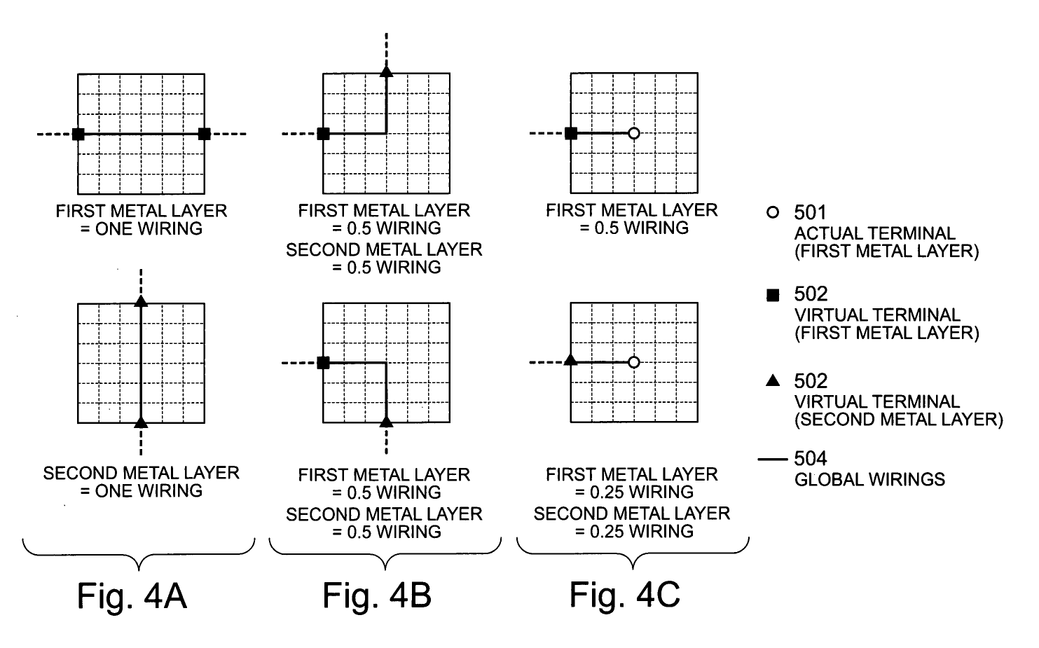

“Unit region” may be a region illustrated in FIGS. 4A-4C.

“Maximum wiring length” may be the maximum wiring length which may be accommodated without occurrence of any short-circuit between the wirings within the unit region in each layer. Within the unit region of FIGS. 4A-4C, the maximum wiring length is 42 units because seven wirings in a length of 6 units can be accommodated within the vertical and horizontal directions when the length of a side of the wiring lattice is defined as 1 unit.

“Wiring passing coefficient” may be defined as a ratio of the length of wiring passing actually to the maximum wiring length within the unit region of each layer. The wiring passing coefficient explained below is considered in this exemplary embodiment as the coefficient used for computing the number of global wirings 504 which can pass each layer within the unit region.

“Global wiring length” may be the length of the global wiring 504.

“Allowable number of global passing wirings” may be the number of global wirings 504 which can pass each layer in the unit region.

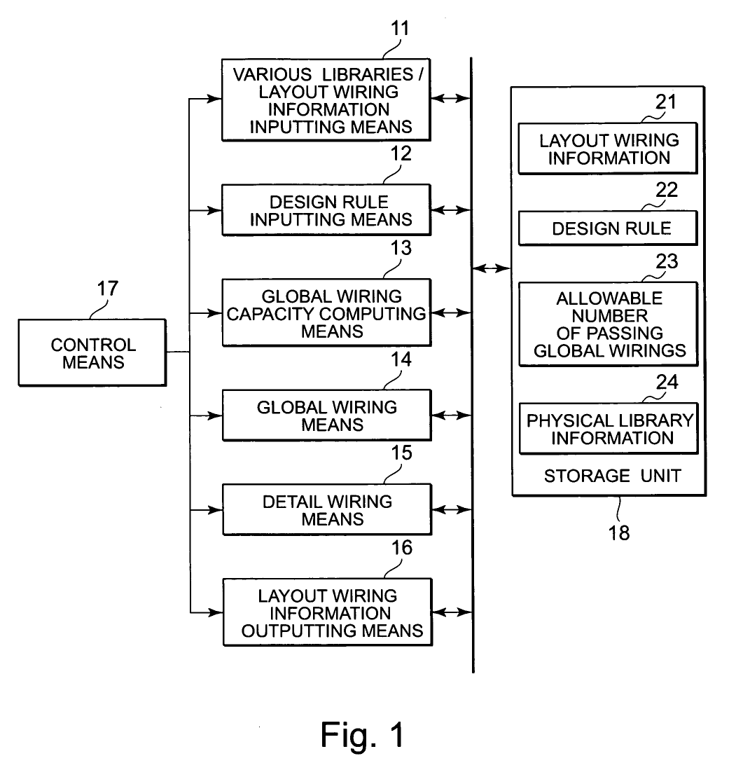

A structure of the exemplary embodiment of the present invention is illustrated in FIG. 1.

Various libraries/layout information inputting means 11 is provided to input the information required for layout of the circuit (e.g., LSI) such as LSI layout information 21 and physical library information 24.

Design rule inputting means 12 is provided to input design rule 22 to be satisfied for polishing an insulating film on the LSI. The insulating film is polished during the layout of the LSI with the CMP method.

Global wiring capacity computing means 13 is provided to compute the allowable number of passing global wirings 23 of each partial region to accommodate the global wiring passing coefficient of unit region within the constant range by referring to design rule 22 inputted with design rule inputting means 12.

Global wiring means 14 is provided to implement global wirings to maintain the number of global wirings 504 in the partial region less than or equal to the allowable number of wirings by referring to the layout information of the actual terminals 501, connecting relationship among the actual terminals 501, and allowable number of passing global wirings 23 computed by global wiring capacity computing means 13. The referring is based on the layout wiring information inputted with various libraries/layout wiring information inputting means 11. Global wiring means 14 updates layout wiring information 21.

Detail wiring means 15 is provided to conduct detail wiring for global wiring determined by the means 14 in each partial region and to update layout wiring information 21.

Layout wiring information outputting means 16 is provided to output the wiring information of the LSI (e.g., layout wiring information 21) altered by detail wiring means 15.

Control means 17 is provided to control various libraries/wiring information inputting means 11, as well as means 12, 13, 14, 15, and 16.

Storage unit 18 is provided to store layout wiring information 21, design rule 22, allowable number of passing global wirings 23, and physical information library 24.

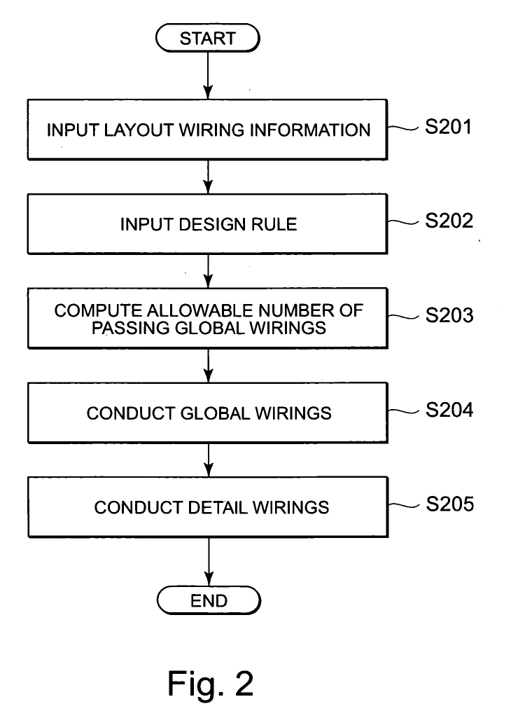

Next, operations of the exemplary embodiment will be explained with reference to FIG. 2.

<Step 201>

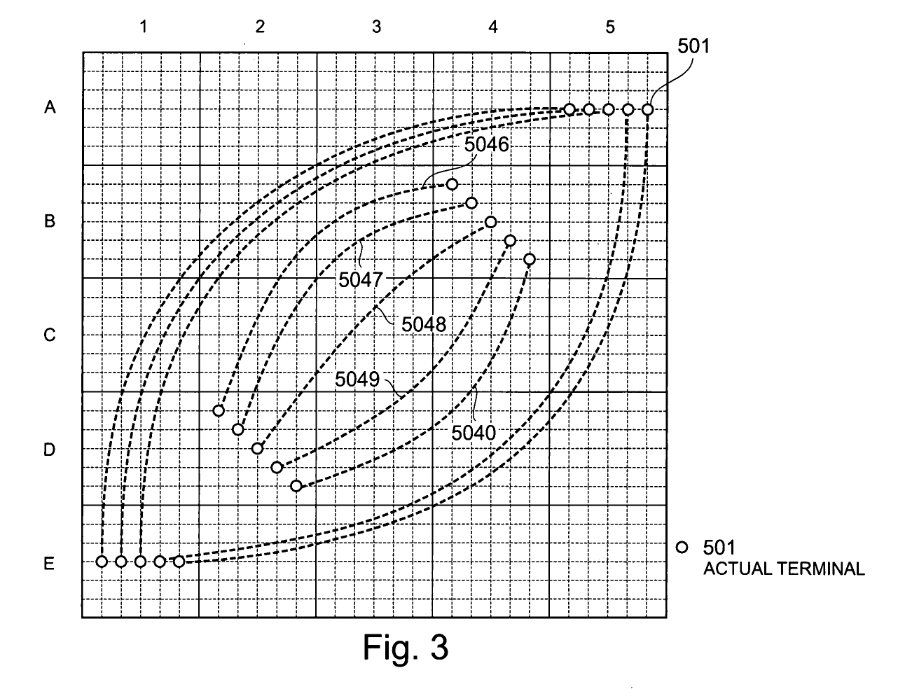

Various libraries/layout wiring information inputting means 11 inputs the information required for layout of the LSI. In FIG. 3, the connecting relationships among the actual terminals 501 are illustrated. Namely, connections between the actual terminals 501 in A-5, E-1 and the actual terminals 501 in B-4, D-2 are illustrated. In this step, the detail wirings 511 and global wirings 5046 . . . 5049, 5040 in the LSI are not yet decided.

<Step 202>

Next, the design rule 22 is inputted by design rule inputting means 12. Design rule 22 is satisfied for processing (e.g., polishing) the insulating film formed on the LSI with the CMP method after completion of the layout of the LSI. For example, design rule 22 includes a size of the partial region for computing wiring density (e.g., boundary line for deciding the partial region) and an upper limit value of the wiring passing coefficient in the unit region in each wiring layer in the LSI.

<Step 203>

Next, an allowable number of passing global wirings 23 is computed by global wiring capacity computing means 13. Here, the wiring density can be equalized by maintaining the number of global wirings 504 in the unit region less than or equal to the specified (e.g., allowable) number of wirings. It is also possible to compute the wiring passing coefficient from estimation of the length of detail wiring passing the unit region and the length of global wiring. In this exemplary embodiment, the number of global wirings 504 in the unit region is restricted instead of limiting the length of the global wirings 504 in the unit region.

Counting of the number of global wirings 504 in the unit region will be explained with reference to FIGS. 4A-4C. First, the global wiring 504 in the length of 6 units passing the same layer in the upper to lower direction and right to left direction of the unit region (two or more virtual terminals 502, of the same layer are connected) is counted as one wiring, as shown in FIG. 4A. When the virtual terminals 502 of different layers are connected, the number of global wirings 504 is divided in accordance with the layer of such virtual terminal 502, as shown in FIG. 4B. Moreover, the wiring which is connected to the actual terminal 501, but does not pass the unit region, is counted as 0.5 wiring, as shown in FIG. 4C.

In this exemplary embodiment, the upper limit value of the wiring passing coefficient is set to 50%. The maximum wiring length of the global wirings 504 which are accommodated in each layer in each unit region is 42 and the upper limit of the wiring passing coefficient is set to 50% by design rule inputting means 12. Therefore, the global wiring length of each layer passing the unit region becomes 21. When the wiring length passing the unit region is assumed as 6 units, the allowable number of passing global wirings in the unit region becomes 3.5 wirings (21/6) in the first metal layer and also becomes 3.5 wirings (21/6) even in the second metal layer.

<Step 204>

Next, the global wirings 504 between the actual terminals 501 are conducted (e.g., executed) by the global wiring means 14. In this exemplary case, the global wirings 504 are conducted so that the number of global wirings 504 in unit region becomes equal to or less than the allowable number of wirings. Specifically, the following sequences are executed.
(1) The allowable passing global wirings are compared with the global wirings 504 which have been wired actually in each layer of each unit region.
(2) When the number of global wirings 504 actually wired exceeds the allowable number of passing global wirings, the global wirings 504 are moved to another region or layer. When moving of the global wiring(s) is necessary, the wiring(s) should be moved so that the wiring length becomes shorter and the wiring passes the region or layer in which the less amount of wirings are laid.

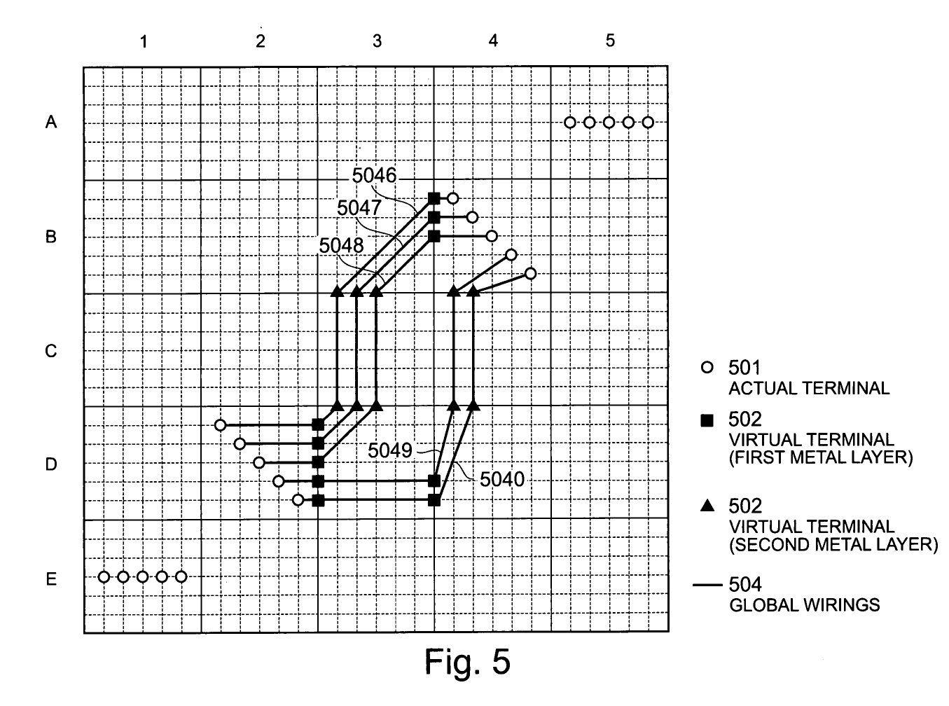

In regard to the order of the global wirings 504, as shown in FIG. 5, the wiring should be started from which is defined with a smaller rectangle surrounding the actual terminal 501 connected to the same wiring (e.g., shorter wiring distance). In this exemplary-embodiment, global wirings 5046 . . . 5049, 5040 are wired first. The completed condition of global wirings 5046 . . . 5049, 5040 is illustrated exemplarily in FIG. 5.

In FIG. 5, three global wirings are shown in the second metal layer of the unit region C-3, and the additional wirings on the second metal layer crossing the unit region C-3 is no longer allowable. Therefore, the wirings 5049 and 5040 connecting the remaining actual terminals 501 pass the unit region C-4. Moreover, in the unit region D-3, the wirings 5046 . . . 5048 are counted as 0.5 wirings in the first and second metal layers, and the wirings 5049, 5040 are respectively counted as one (1) wiring in the first metal layer. Accordingly, the number of global wirings in this unit region D-3 is counted as 3.5 wirings (0.5×3+1×2) in the first metal layer and as 1.5 wirings (0.5×3) in the second metal layer. These numbers of wirings are equal to or less than the allowable number of passing global wirings.

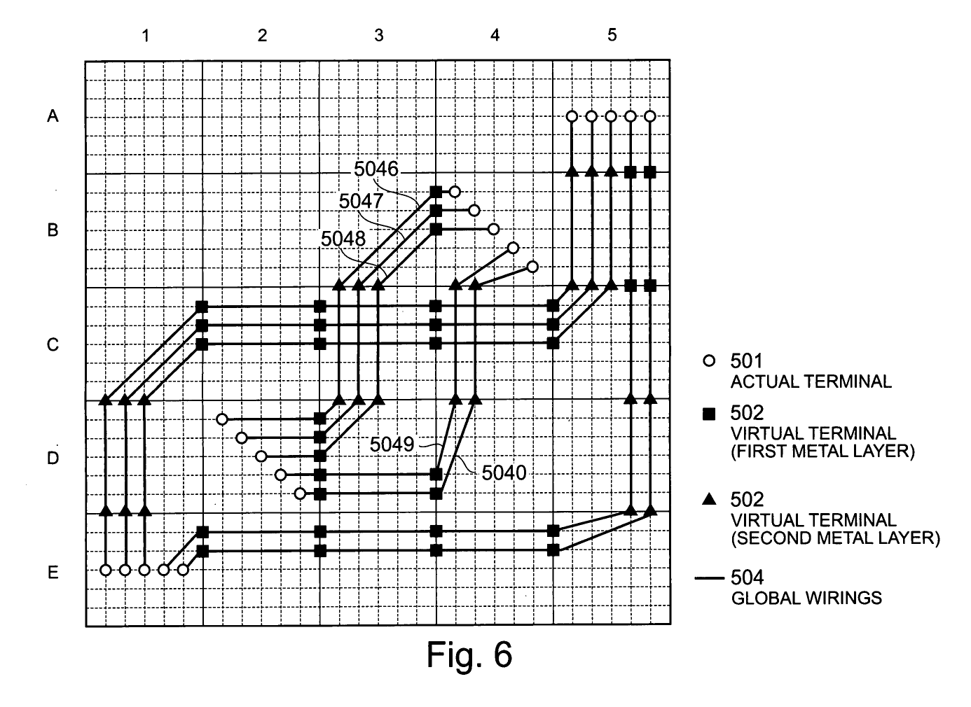

FIG. 6 illustrates the global wirings being completed for all wirings. The information after the completion of the global wirings is written into layout wiring information 21 shown in FIG. 1.

<Step 205>

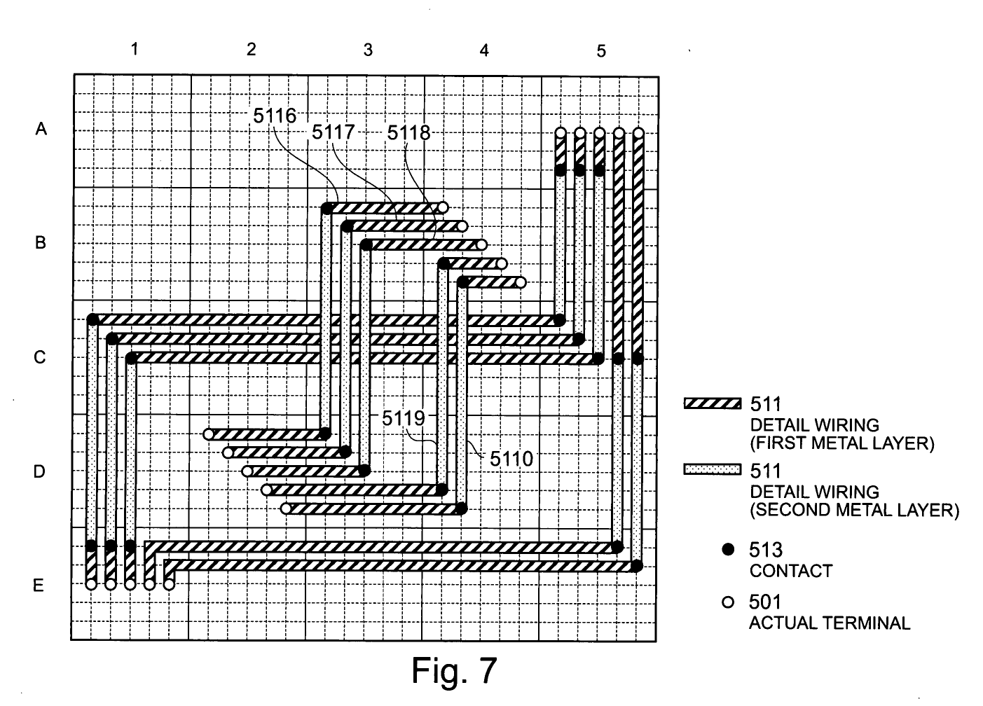

Next, detail wiring means 15 conducts (e.g., executes) the detail wirings 511 to each partial region for the global wirings decided by global wiring means 14. A wiring diagram after the detail wirings 511 is illustrated in FIG. 7. Moreover, detail wiring means 15 updates layout wiring information 21, and layout wiring information Outputting means 16 outputs layout wiring information 21 of the LSI updated by detail wiring means 15.

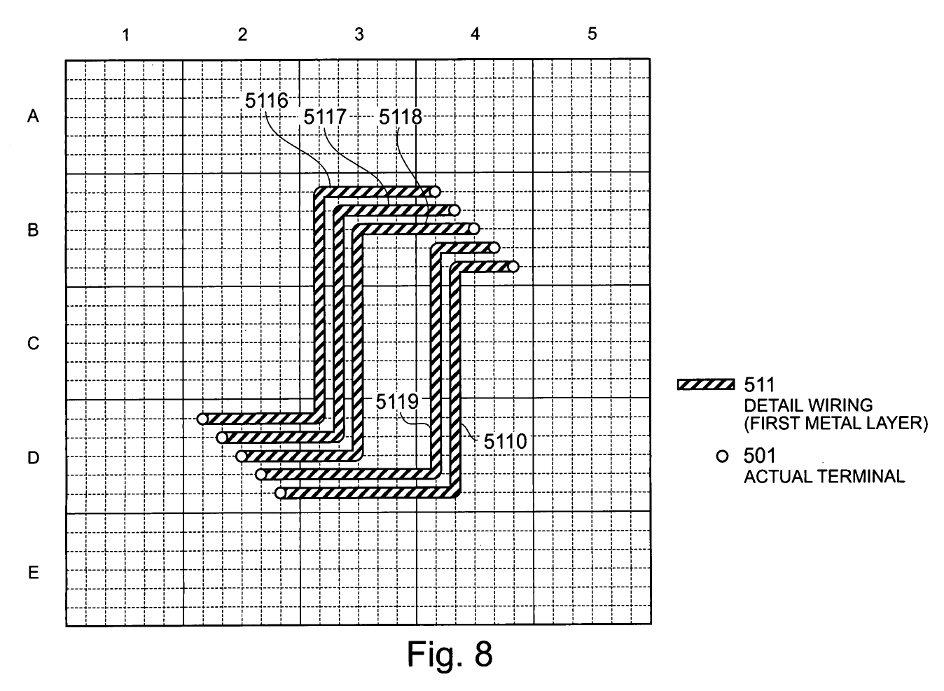

In this exemplary embodiment, two wiring layers are provided. However, three or 7 more wiring layers may also be used, or for that matter, one layer may be used. Another exemplary diagram illustrating the condition where the detail wirings on a single layer structure have been completed is shown in FIG. 8. Detail wirings 5116 . . . 5119, 5110 between the actual terminals 501 are executed. The three detail wirings 5116, 5117, and 5118 are shown in the unit region C-3. Since the additional wirings crossing the unit region C-3 is not allowable, the detail wirings 5119 and 5110 connecting the remaining actual terminals 501 pass the unit region C-4.

In addition, the size of the unit region is defined as 6×6, but the present invention is not limited thereto and the size of the unit region can be varied as required.

With the exemplary method explained above, the extra processes for design of an LSI (e.g., backward processes such as manual correction of the signal wirings to equalize the wiring density, the amount of data and processing time for embedding the dummy wirings to the region where the wiring density is small) can be reduced by automatically moving a wiring to another region, to make uniform a number of wirings in the LSI considering the wiring passing coefficient.

This invention also applies to a method of using a wiring layout by processing a circuit “Processing” may mean using, manufacturing, and/or designing a circuit.

While this invention has been described with reference to exemplary embodiments, this description is not intended as limiting. Various modifications of the illustrative embodiments, as well as other embodiments of the invention, will be apparent to persons skilled in the art upon taking description as a whole. It is, therefore, contemplated that the appended claims will cover any such modifications or embodiments as fall within the true scope of the invention.

Further, the inventor's intent is to encompass all equivalents of all the elements of the claimed invention even if the claims are amended during prosecution.

This application is based on Japanese Patent Application No. 2004-302723 filed on Oct. 18, 2004 and including specification, claims, drawings and summary. The disclosure of the above Japanese Patent Application is incorporated herein by reference in its entirety.

What is claimed is:

1. A circuit wiring laying-out apparatus comprising:
a wiring device that moves automatically a wiring in a first region to a second region, to make uniform a number of wirings in said circuit.

2. The circuit wiring laying-out apparatus according to claim 1, wherein:
said circuit comprises an LSI (Large Scale Integrated Circuit).

3. The circuit wiring laying-out apparatus according to claim 1, wherein:
when a number of said wirings in said first region exceeds a number of allowable wirings, said wiring device moves said wiring to said second region.

4. The circuit wiring laying-out apparatus according to claim 1, wherein:
said circuit has a single wiring layer.

5. The circuit wiring laying-out apparatus according to claim 3, wherein:
said circuit includes a plurality of wiring layers and said second region is on a second wiring layer.

6. The circuit wiring laying-out apparatus according to claim 1, wherein:
said wiring device is devoid of a dummy wiring.

7. The circuit wiring laying-out apparatus according to claim 3, further comprising:
a global wiring capacity computing device that computes said number of allowable wirings passing said first region.

8. The circuit wiring laying-out apparatus according to claim 7, said wiring device comprising:
when said number of said wirings in said first region exceeds said number of allowable wirings, a global wiring device that executes said wiring so that said number of wirings passing said first region becomes substantially equal to or less than said allowable number of wirings.

9. The circuit wiring laying-out apparatus according to claim 8, wherein:
when said number of said wirings in said first region exceeds said number of allowable wirings, said global wiring device moves said wiring to said second region so that a length of wiring becomes shorter and said wiring passes the second region in which a less number of wirings are laid.

10. The circuit wiring laying-out apparatus according to claim 7, further comprising:
a various libraries/layout information inputting device that inputs an information required for laying-out of said circuit;
a design rule inputting device that inputs a design rule to be satisfied for processing an insulating film on said circuit;
said global wiring capacity computing device that computes said number of allowable wirings passing each partial region to accommodate a global wiring passing coefficient of a unit region within a constant range by referring to said design rule inputted with said design rule inputting device;
said global wiring device that implements a global wiring and updates a laying-out wiring information to maintain said number of global wirings in said partial region less than or equal to said allowable number of wirings by referring to said layout information of actual terminal, said global wiring device connecting relationship among said actual terminals, and said allowable number of passing global wirings from said laying-out wiring information inputted with said various libraries/layout information inputting device;
a detail wiring device that executes detail wiring in each said partial region and updates said layout wiring information, for said global wiring determined by said global wiring device; and
a laying-out wiring information outputting device that outputs said wiring information of circuit altered by said detail wiring device.

11. A circuit wiring laying-out apparatus, comprising:
means for moving automatically a wiring in a first region to a second region to make uniform a number of wirings in said circuit; and
means for computing an allowable number of wirings passing said first region, wherein,
when a number of said wirings in said first region exceeds a number of allowable wirings, said wiring device moves said wiring to said second region.

12. A method of laying-out a circuit wiring, comprising:
moving automatically a wiring in a first region to a second region to make uniform a number of wirings in said circuit.

13. The method of laying-out a circuit wiring according to claim 12, further comprising:
providing said circuit to have an LSI (Large Scale Integrated Circuit).

14. The method of laying-out the circuit wiring according to claim 12, further comprising:
when a number of said wirings in said first region exceeds a number of allowable wirings, moving said wiring to said second region.

15. The method of laying-out the circuit wiring according to claim 12, further comprising:
providing said circuit to have a single layer.

16. The method of laying-out the circuit wiring according to claim 14, further comprising:
providing said circuit to include a plurality of wiring layers and said second region is on a second wiring layer.

17. The method of laying-out the circuit wiring according to claim 12, further comprising:
providing said circuit wiring devoid of a dummy wiring.

18. The method of laying-out the Circuit wiring according to claim 14, further comprising:
computing said number of allowable wirings passing said first region.

19. The method of laying-out the circuit wiring according to claim 18, further comprising:
when said number of said wirings in said first region exceeds said number of allowable wirings, executing said wiring so that said number of wirings passing said first region becomes substantially equal to or less than said allowable number of wirings.

20. The method of laying-out the circuit wiring according to claim 18, wherein:
when said number of said wirings in said first region exceeds said number of allowable wirings, moving said wiring to said second region so that a length of wiring becomes shorter and said wiring passes said second region in which a less number of wirings are laid.

21. The method of laying-out the circuit wiring according to claim 19, comprising:
inputting an information required for laying-out of said circuit;
inputting a design rule to be satisfied for processing an insulating film on said circuit;
computing said number of allowable wirings passing each partial region to accommodate a global wiring passing coefficient of a unit region within a constant range by referring to said design rule;
implementing global wiring and updating a laying-out wiring information to maintain said number of global wirings in said partial region less than or equal to said allowable number of wirings by referring to said layout information of actual terminal, said global wiring device connecting relationship among said actual terminals, and said allowable number of passing global wirings from said laying-out wiring information inputted with said various libraries/layout information inputting device;
executing detail wiring in each said partial region and updating said layout wiring information, for said global wiring; and
outputting said wiring information of said circuit.

22. A signal-bearing medium embodying a program of machine-readable instructions executable by a digital processing apparatus, said program causing a wiring laying-out apparatus to perform a method of claim 12.

23. A wiring layout, comprising:
a substantially uniform number of wirings devoid of a dummy wiring.

24. A method of using a wiring layout, comprising:
processing a circuit including a substantially uniform number of wirings and devoid of a dummy wiring based on said wiring layout.
